(19) United States
(12) Patent Application Publication
(10) Pub. No.: US 2008/0265972 A1
(43) Pub. Date: Oct. 30, 2008

(54) OUTPUT CIRCUIT AND MULTI-OUTPUT CIRCUIT

(76) Inventors: Emi Nakamura, Kyoto (JP); Hiroki Matsunaga, Osaka (JP)

Correspondence Address: MCDERMOTT WILL & EMERY LLP, 600 13TH STREET, NW, WASHINGTON, DC, 20005-3096, US

(21) Appl. No.: 12/048,787

(22) Filed: Mar. 14, 2008

(30) Foreign Application Priority Data
Apr. 24, 2007 (JP) 2007-114304

(51) Int. Cl. H03L 5/00

(52) U.S. Cl. 327/333

(57) ABSTRACT

An output circuit includes a high-side transistor, a low-side transistor, a gate protection circuit, a level shift circuit, and a pre-driver circuit. The level shift circuit interrupts a current path from an output terminal to the level shift circuit after a predetermined time has passed since the high-side transistor was switched OFF.

### BACKGROUND OF THE INVENTION

1. Field of the Invention

The present invention relates to an output circuit and a multi-output circuit and, more particularly, to a multi-channel capacitive load drive circuit for driving a capacitive load, such as a plasma display or the like.

2. Description of the Related Art

FIG. 15 shows an exemplary circuit configuration of an output circuit including a high-withstand voltage driver in a conventional multi-channel capacitive load drive circuit.

The output circuit of FIG. 15 includes a high-withstand voltage driver 26 having a high-withstand voltage output circuit 9 and a level shift circuit 8, and a pre-driver circuit 7.

The high-withstand voltage output circuit 9 included in the high-withstand voltage driver 26 includes a half-bridge circuit 34 and a gate protection circuit 10. The half-bridge circuit 34 includes a high-side transistor 13 and a low-side transistor 14. The gate protection circuit 10, which includes a Zener diode 11 and a resistor 12, protects the gate of the high-side transistor 13. The level shift circuit 8 included in the high-withstand voltage driver 26 drives the high-side transistor 13.

The pre-driver circuit 7, which includes an inverter 31 and a NOR circuit 35, drives the level shift circuit 8 and the low-side transistor 14. The high-withstand voltage output circuit 9 has an output terminal 4 which is connected to a common connection terminal of the high-side transistor 13 and the low-side transistor 14. A reference power supply terminal 1 is a terminal having a reference potential. A low-voltage power supply terminal 2 is a terminal of a low-voltage power supply of about 5 V. A high-voltage power supply terminal 3 is a terminal of a high-voltage power supply of 100 V or more. Input signals from a low-withstand voltage control section (not shown) are input to control input terminals 5 and 6.

Next, an operation of the thus-configured output circuit including the high-withstand voltage driver 26 in the conventional multi-channel capacitive load drive circuit, will be described.

FIG. 16 is a timing diagram for describing the operation of the thus-configured output circuit including the high-withstand voltage driver 26 in the conventional multi-channel capacitive load drive circuit.

FIG. 16 shows input signals IN and HIZ which are input from the low-withstand voltage control section to the control input terminals 5 and 6, output signals IN1 and IN2 of the pre-driver circuit 7 which are used to drive the level shift circuit 8 in accordance with the input signals IN and HIZ, an output signal IN3 of the pre-driver circuit 7 which is used to drive the low-side transistor 14 in accordance with the input signals IN and HIZ, an output signal IN4 of the level shift circuit 8 which is used to drive the high-side transistor 13 in accordance with the output signals IN1 and IN2 of the pre-driver circuit 7, a gate drive signal P2G of a thick-film gate P-type MOS transistor 16 included in the level shift circuit 8, a gate-source voltage GH of the high-side transistor 13 which is determined by the gate protection circuit 10 which has received the output signal IN4 of the level shift circuit 8, and a voltage waveform OUT of the output terminal 4 of the high-withstand voltage output circuit 9 which is output in accordance with the output signal IN3 of the pre-driver circuit 7.

Here, a case where a signal having the GND level is input to the control input terminal 6, so that the input signal HIZ is at the L level (GND), will be described.

Initially, when a signal having the GND level is input to the input terminal 5, so that the input signal IN goes to the L level (GND), then the output signal IN1 goes to the L level (GND) and the output signal IN2 goes to the H level (VDD), so that the gate drive signal P2G goes to the L level (GND) and the output signal IN4 goes to the H level (VDDH). Therefore, due to the Zener diode 11, the gate-source voltage GH becomes OUT+Vz (breakdown voltage), which is higher than or equal to a threshold voltage Vth (N1) of the high-side transistor 13, so that the high-side transistor 13 is switched ON. Also, the output signal IN3 goes to the L level (GND), so that the low-side transistor 14 is switched OFF. As a result, the output voltage waveform OUT goes to the H level (VDDH).

Next, when a signal having the VDD level is input to the input terminal 5, so that the input signal IN goes to the H level (VDD), then the output signal IN1 goes to the H level (VDD) and the output signal IN2 goes to the L level (GND), so that the gate drive signal P2G goes to the H level (VDDH) and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (N1) of the high-side transistor 13. As a result, the high-side transistor 13 is switched OFF. Also, the output signal IN3 goes to the H level (VDD), so that the low-side transistor 14 is switched ON. As a result, the output voltage waveform OUT goes to the L level (GND).

On the other hand, a case where a signal having the VDD level is input to the control input terminal 6, will be described.

In this case, no matter whether a signal input to the input terminal 5 has the GND level or the VDD level, the output signal IN1 goes to the H level (VDD) and the output signal IN2 goes to the L level (GND), so that the gate drive signal P2G goes to the H level (VDDH). As a result, a thin-film gate N-type MOS transistor 18 included in the level shift circuit 8 is switched ON. In this case, the Zener diode 11 included in the gate protection circuit 10 is forward-biased, so that the gate-source voltage GH becomes OUT-VFD (Zener forward voltage), which is lower than or equal to the threshold voltage Vth (N1) of the high-side transistor 13. As a result, the high-side transistor 13 is switched OFF. Also, the output signal IN3 goes to the L level (GND), so that the low-side transistor 14 is switched OFF. In this case, the thin-film gate N-type MOS transistor 18 is switched ON, so that a load current flows in via the Zener diode 11 from the output terminal 4. As a result, the output voltage waveform OUT goes to the L level (GND).

Patent Document 1: Japanese Unexamined Patent Application Publication No. 2005-20142 (FIG. 4)

In the high-withstand voltage driver 26 of the conventional multi-channel capacitive load drive circuit, a load current path is formed by the thin-film gate N-type MOS transistor 18 included in the level shift circuit 8, and the Zener diode 11, and therefore, the output terminal 4 cannot be caused to have a complete high impedance.

Also, since a capacitive load of several hundreds of picofarads is typically discharged over a long time by the compact thin-film gate N-type MOS transistor 18, this transistor may be broken due to, for example, heat generated in itself. In order to prevent the transistor from being broken, the size of the transistor may be increased. In this case, however, the chip area disadvantageously increases.

### SUMMARY OF THE INVENTION

In view of the above-described problems, the present invention has been achieved. An object of the present invention is to provide an output circuit and a multi-output circuit in which a path through which the load current flows from an output terminal via a Zener diode to a level shift circuit is interrupted so that the output terminal is caused to have a complete high impedance.

According to a first embodiment of the present invention, an output circuit includes a high-side transistor, a low-side transistor, a gate protection circuit for protecting a gate voltage of the high-side transistor, a level shift circuit for driving the high-side transistor via the gate protection circuit, and a pre-driver circuit for driving the level shift circuit and the low-side transistor. A connection point of the high-side transistor and the low-side transistor serves as an output terminal. The level shift circuit interrupts a current path from the output terminal to the level shift circuit after a predetermined time has passed since the high-side transistor was switched OFF.

In the output circuit of the first embodiment of the present invention, the level shift circuit goes to a high-impedance state after the high-side transistor is switched OFF, thereby interrupting the current path.

The output circuit of the first embodiment of the present invention further includes a delay line including a plurality of inverters connected to each other in series, for setting the predetermined time.

In the output circuit of the first embodiment of the present invention, the predetermined time is longer than a time required for the high-side transistor to be completely switched OFF.

In the output circuit of the first embodiment of the present invention, the delay line cancels the interruption of the current path without setting the predetermined time.

A multi-output circuit includes a plurality of output circuits, wherein each output circuit is the output circuit of the first embodiment of the present invention, a shift register for successively outputting outputs of the output circuits, and one or more delay lines each including a plurality of inverters connected to each other in series, for setting the predetermined times for the respective corresponding level shift circuits.

According to a second embodiment of the present invention, an output circuit includes a high-side transistor, a high-side recirculating diode connected in parallel with the high-side transistor, a low-side transistor, a low-side recirculating diode connected in parallel with the low-side transistor, a gate protection circuit for protecting a gate voltage of the high-side transistor, a level shift circuit for driving the high-side transistor via the gate protection circuit, and a pre-driver circuit for driving the level shift circuit and the low-side transistor. A connection point of the high-side transistor and the low-side transistor serves as an output terminal. The level shift circuit interrupts a current path from the output terminal to the level shift circuit after a predetermined time has passed since the high-side transistor was switched OFF.

In the output circuit of the second embodiment of the present invention, the level shift circuit goes to a high-impedance state after the high-side transistor is switched OFF, thereby interrupting the current path.

The output circuit of the second embodiment of the present invention further includes a delay line including a plurality of inverters connected to each other in series, for setting the predetermined time.

In the output circuit of the second embodiment of the present invention, the predetermined time is longer than a time required for the high-side transistor to be completely switched OFF.

In the output circuit of the second embodiment of the present invention, the delay line cancels the interruption of the current path without setting the predetermined time.

A multi-output circuit includes a plurality of output circuits, wherein each output circuit is the output circuit of the second embodiment of the present invention, a shift register for successively outputting outputs of the output circuits, and one or more delay lines each including a plurality of inverters connected to each other in series, for setting the predetermined times for the respective corresponding level shift circuits.

According to a third embodiment of the present invention, an output circuit includes a high-side transistor, a low-side transistor, a gate protection circuit for protecting a gate voltage of the high-side transistor, a level shift circuit for driving the high-side transistor via the gate protection circuit, and a pre-driver circuit for driving the level shift circuit and the low-side transistor. A connection point of the high-side transistor and the low-side transistor serves as an output terminal. The output circuit further includes a diode between the level shift circuit and the gate protection circuit.

According to a fourth embodiment of the present invention, an output circuit includes a high-side transistor, a high-side recirculating diode connected in parallel with the high-side transistor, a low-side transistor, a low-side recirculating diode connected in parallel with the low-side transistor, a gate protection circuit for protecting a gate voltage of the high-side transistor, a level shift circuit for driving the high-side transistor via the gate protection circuit, and a pre-driver circuit for driving the level shift circuit and the low-side transistor. A connection point of the high-side transistor and the low-side transistor serves as an output terminal. The output circuit further includes a diode between the level shift circuit and the gate protection circuit.

As described above, according to the output circuit and multi-output circuit of the present invention, a gate protection circuit including a Zener diode is employed so as to use a high-side transistor having a thin gate oxide film, so that a high-withstand voltage output terminal can be caused to have a complete high impedance.

### BRIEF DESCRIPTION OF THE DRAWINGS

FIG. 1 is a diagram showing an exemplary circuit configuration of an output circuit including a high-withstand voltage driver in a multi-channel capacitive load drive circuit according to a first embodiment of the present invention.

FIG. 2 is a timing diagram for describing an operation of the output circuit including the high-withstand voltage driver in the multi-channel capacitive load drive circuit of the first embodiment of the present invention.

FIG. 3 is a diagram showing an exemplary circuit configuration of an output circuit including a high-withstand voltage driver in a multi-channel capacitive load drive circuit according to a second embodiment of the present invention.

FIG. 4 is a timing diagram for describing an operation of the output circuit including the high-withstand voltage driver in the multi-channel capacitive load drive circuit of the second embodiment of the present invention.

FIG. 5 is a diagram showing an exemplary circuit configuration of an output circuit including a high-withstand voltage driver in a multi-channel capacitive load drive circuit according to a third embodiment of the present invention.

FIG. 6 is a timing diagram for describing an operation of the output circuit including the high-withstand voltage driver in the multi-channel capacitive load drive circuit of the third embodiment of the present invention.

FIG. 7 is a diagram showing an exemplary circuit configuration of an output circuit including a high-withstand voltage driver in a multi-channel capacitive load drive circuit according to a fourth embodiment of the present invention.

FIG. 8 is a timing diagram for describing an operation of the output circuit including the high-withstand voltage driver in the multi-channel capacitive load drive circuit of the fourth embodiment of the present invention.

FIG. 9 is a diagram showing an exemplary circuit configuration of an output circuit including a high-withstand voltage driver in a multi-channel capacitive load drive circuit according to a fifth embodiment of the present invention.

FIG. 10 is a timing diagram for describing an operation of the output circuit including the high-withstand voltage driver in the multi-channel capacitive load drive circuit of the fifth embodiment of the present invention.

FIG. 11 is a diagram showing an exemplary circuit configuration of an output circuit including a high-withstand voltage driver in a multi-channel capacitive load drive circuit according to a sixth embodiment of the present invention.

FIG. 12 is a timing diagram for describing an operation of the output circuit including the high-withstand voltage driver in the multi-channel capacitive load drive circuit of the sixth embodiment of the present invention.

FIG. 13 is a diagram showing an exemplary circuit configuration of an output circuit including a high-withstand voltage driver in a multi-channel capacitive load drive circuit according to a seventh embodiment of the present invention.

FIG. 14 is a timing diagram for describing an operation of the output circuit including the high-withstand voltage driver in the multi-channel capacitive load drive circuit of the seventh embodiment of the present invention.

FIG. 15 is a diagram showing an exemplary circuit configuration of an output circuit including a high-withstand voltage driver in a conventional multi-channel capacitive load drive circuit.

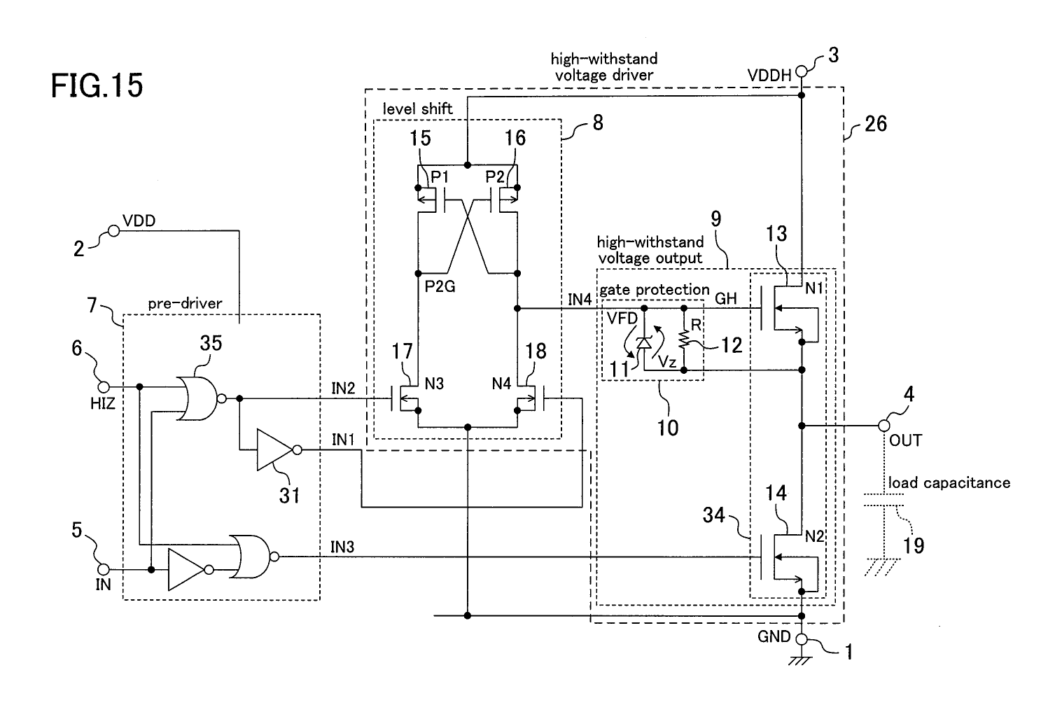

FIG. 16 is a timing diagram for describing an operation of the output circuit including the high-withstand voltage driver in the conventional multi-channel capacitive load drive circuit.

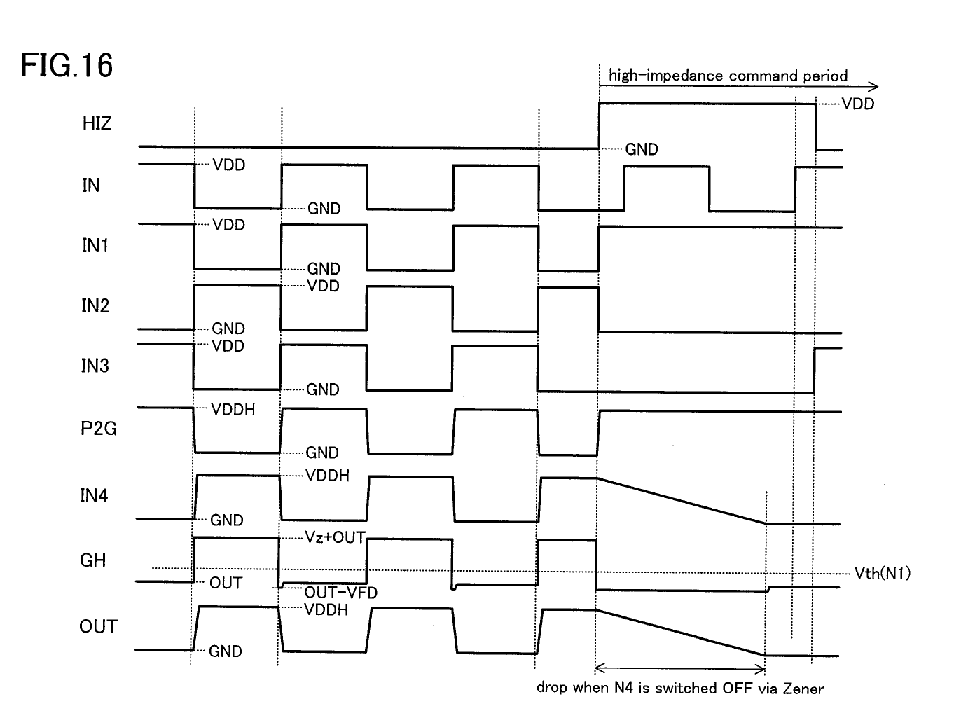

### DETAILED DESCRIPTION OF THE PREFERRED EMBODIMENTS

Hereinafter, embodiments of the present invention will be described with reference to the accompanying drawings.

### First Embodiment

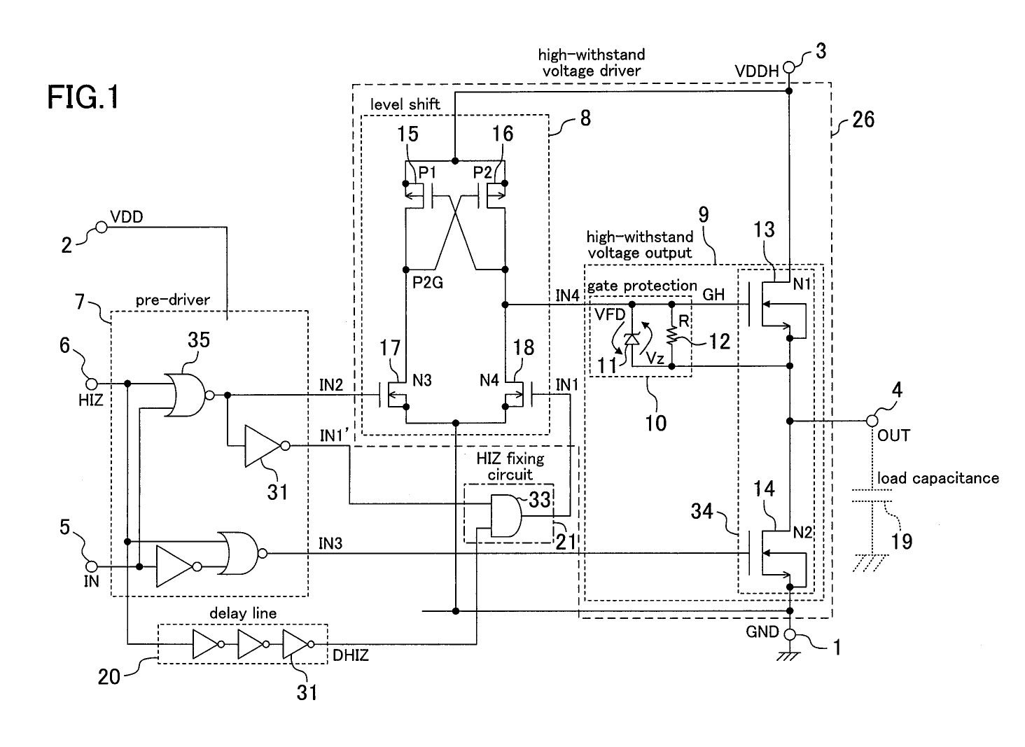

FIG. 1 shows an exemplary circuit configuration of an output circuit including a high-withstand voltage driver in a multi-channel capacitive load drive circuit according to a first embodiment of the present invention.

The output circuit of FIG. 1 includes a high-withstand voltage driver 26, a pre-driver circuit 7, a delay line 20, and an HIZ fixing circuit 21. The high-withstand voltage driver 26 includes a high-withstand voltage output circuit 9 and a level shift circuit 8.

The high-withstand voltage output circuit 9 included in the high-withstand voltage driver 26 includes a half-bridge circuit 34 and a gate protection circuit 10. The half-bridge circuit 34 includes a high-side transistor 13 and a low-side transistor 14. The gate protection circuit 10, which includes a Zener diode 11 and a resistor 12, protects the gate of the high-side transistor 13. The level shift circuit 8 included in the high-withstand voltage driver 26, which includes thick-film gate P-type MOS transistors 15 and 16 and thin-film gate N-type MOS transistors 17 and 18, drives the high-side transistor 13.

The pre-driver circuit 7, which includes an inverter 31 and a NOR circuit 35, drives the high-withstand voltage driver 26 and the low-side transistor 14 in accordance with a signal which is input to the control input terminal 5 from a low-withstand voltage control section (not shown), to charge and discharge a load capacity 19. Note that an output terminal 4 of the high-withstand voltage output circuit 9 is connected to a common connection terminal of the high-side transistor 13 and the low-side transistor 14. A reference power supply terminal 1 is a terminal having a reference potential. A low-voltage power supply terminal 2 is a terminal of a low-voltage power supply of about 5 V. A high-voltage power supply terminal 3 is a terminal of a high-voltage power supply of 100 V or more. Input signals from the low-withstand voltage control section (not shown) are input through the control input terminals 5 and 6 to the pre-driver 7. The level shift circuit 8, the high-side transistor 13, and the low-side transistor 14 are forced to go to the high-impedance state, via the delay line 20, the HIZ fixing circuit 21, and the pre-driver circuit 7, in accordance with a signal which is input to the control input terminal 6 irrespective of the state of the control input terminal 5. The high-side transistor 13 is used to output a high level, and the low-side transistor 14 is used to output a low level.

The delay line 20 includes a plurality of inverters 31. The HIZ fixing circuit 21 includes an AND circuit 33.

Next, an operation of the output circuit including the high-withstand voltage driver 26 in the thus-configured multi-channel capacitive load drive circuit of the first embodiment of the present invention, will be described.

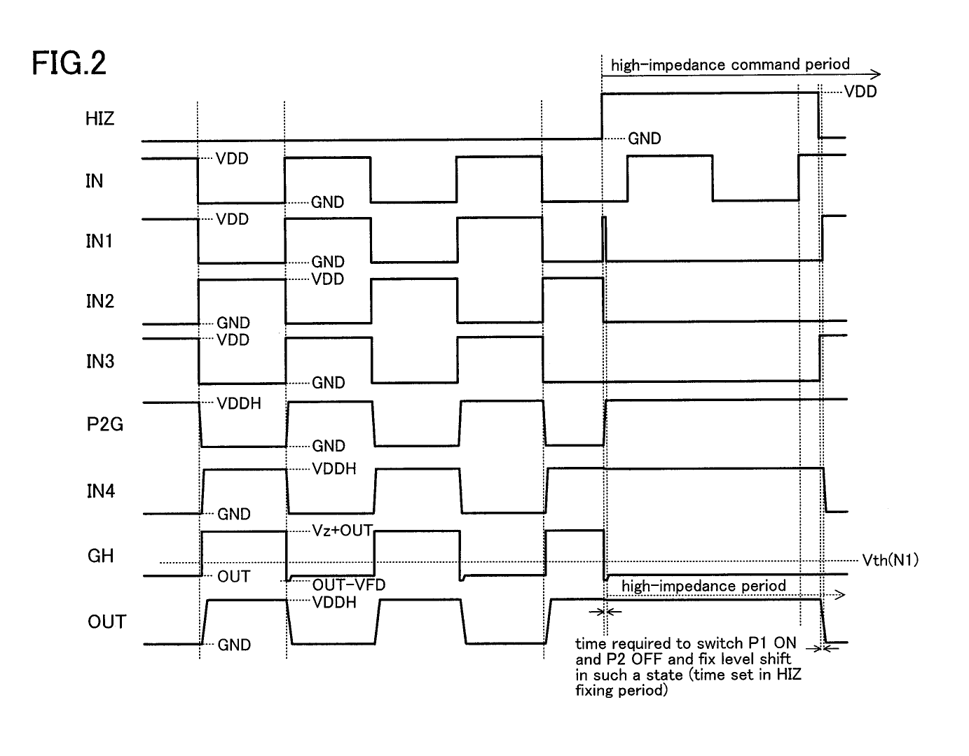

FIG. 2 is a timing diagram for describing the operation of the output circuit including the high-withstand voltage driver 26 in the multi-channel capacitive load drive circuit of the first embodiment of the present invention.

FIG. 2 shows an input signal HIZ which is input from the low-withstand voltage control section to the control input terminal 6, an input signal IN which is input from the low-withstand voltage control section to the control input terminal 5, an output signal IN2 of the pre-driver circuit 7 which is used to drive the level shift circuit 8 in accordance with the input signal IN and the input signal HIZ, an output signal IN1 of the HIZ fixing circuit 21, an output signal IN3 of the pre-driver circuit 7 which is used to drive the low-side transistor 14 in accordance with the input signal IN and the input signal HIZ, output signals P2G and IN4 of the level shift circuit 8 which are used to drive the high-side transistor 13 in accordance with the output signal IN1 of the HIZ fixing circuit 21 which is obtained by an AND operation of an output signal IN1′ of the pre-driver circuit 7 and an output signal DHIZ which is the input signal HIZ delayed by the delay line 20, a gate-source voltage GH of the high-side transistor 13 which is determined by the gate protection circuit 10 which has received the output signal IN4 of the level shift circuit 8, and an output voltage waveform OUT of the high-withstand voltage output circuit 9 which is output in accordance with the output signal IN3 of the pre-driver circuit 7.

Here, a case where a signal having the GND level is input to the control input terminal 6, so that the input signal HIZ is at the L level (GND), will be described.

In this case, the output signal DHIZ of the delay line 20 goes to the H level (VDD), so that the HIZ fixing circuit 21 can output the output signal IN1 having the same logical value as that of the output signal IN1′.

In this case, initially, when a signal having the GND level is input to the input terminal 5, so that the input signal IN goes to the L level (GND), then the output signal IN1′ goes to the L level (GND), and therefore, the output signal IN1 also goes to the L level (GND). Also, the output signal IN2 goes to the H level (VDD), the output signal P2G goes to the L level (GND), and the output signal IN4 goes to the H level (VDDH). Therefore, due to the Zener diode 11, the gate-source voltage GH becomes OUT+Vz (breakdown voltage), which is higher than or equal to the threshold voltage Vth (N1) of the high-side transistor 13, so that the high-side transistor 13 is switched ON. Also, the output signal IN3 goes to the L level (GND), so that the low-side transistor 14 is switched OFF. As a result, the output voltage waveform OUT goes to the H level (VDDH).

Next, when a signal having the VDD level is input to the input terminal 5, so that the input terminal IN goes to the H level (VDD), then the output signal IN1′ goes to the H level (VDD), and therefore, the output signal IN1 also goes to the H level (VDD). Also, the output signal IN2 goes to the L level (GND), the output signal P2G goes to the H level (VDDH), and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (N1) of the high-side transistor 13, and therefore, the high-side transistor 13 is switched OFF. Thereafter, the gate-source voltage GH returns to the same potential as that of the output terminal 4 due to the resistor 12. Also, the output signal IN3 goes to the H level (VDD), so that the low-side transistor 14 is switched ON. As a result, the output voltage waveform OUT goes to the L level (GND).

On the other hand, a case where a signal having the VDD level is input to the control input terminal 6 so as to cause the output terminal 4 to go to the high-impedance state, will be described.

In this case, when the input signal HIZ is at the H level (VDD), then the output signal IN1′ of the pre-driver circuit 7 goes to the H level (VDD), and the output signal DHIZ of the delay line 20 is initially at the H level (VDD) due to a delay, so that the HIZ fixing circuit 21 outputs the output signal IN1 having the same logical value as that of the output signal IN1′. Therefore, the output signal IN1 goes to the H level (VDD). Also, the output signal IN2 goes to the L level (GND), the output signal P2G goes to the H level (VDDH), and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (N1) of the gate of the high-side transistor 13. As a result, the high-side transistor 13 is switched OFF.

In this case, since the thin-film gate N-type MOS transistor 18 is switched ON, a load current flows in from the output terminal 4 via the Zener diode 11. Therefore, the output voltage waveform OUT gradually decreases toward the L level (GND). However, since the output of the delay line 20 goes to the L level (GND) after a predetermined time has passed, the output signal IN1 goes to the L level (GND). Therefore, the thin-film gate N-type MOS transistor 18 is switched OFF, so that a path through which the load current flows in from the output terminal 4 via the Zener diode 11 is interrupted. As a result, the output terminal 4 goes to the high-impedance state.

Here, the predetermined time by which a signal is delayed in the delay circuit 20 may be a time which allows the high-side transistor 13 to be completely switched OFF and the output signal P2G of the level shift circuit 8 to go to the H level (VDDH), so that the thick-film gate P-type MOS transistor 16 is latched at the OFF state. This time is typically sufficient when it is of the order of several hundreds of nanoseconds, and the thin-film gate N-type MOS transistor 18 has a size which is smaller by two or more orders of magnitude than that of the low-side transistor 14 which rapidly discharges the load capacity 19. Therefore, the output voltage waveform OUT goes to the high-impedance state with substantially no change.

### Second Embodiment

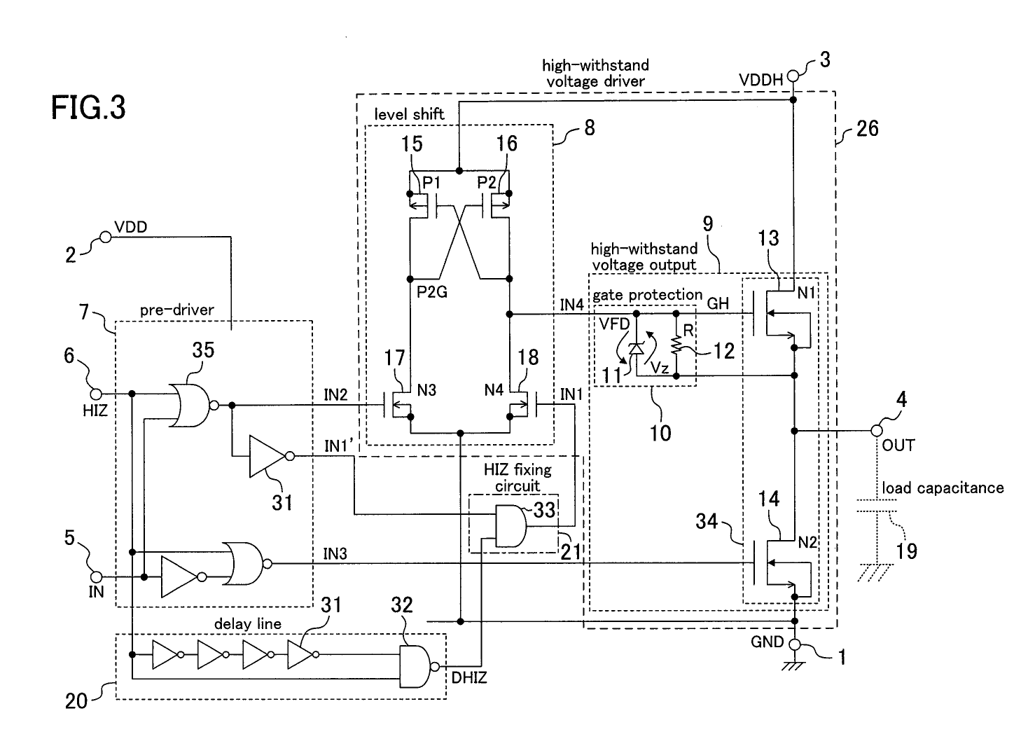

FIG. 3 shows an exemplary circuit configuration of an output circuit including a high-withstand voltage driver in a multi-channel capacitive load drive circuit according to a second embodiment of the present invention.

The output circuit of FIG. 3 includes a high-withstand voltage driver 26, a pre-driver circuit 7, a delay line 20, and an HIZ fixing circuit 21. The high-withstand voltage driver 26 includes a high-withstand voltage output circuit 9 and a level shift circuit 8.

The high-withstand voltage output circuit 9 included in the high-withstand voltage driver 26 includes a half-bridge circuit 34 and a gate protection circuit 10. The half-bridge circuit 34 includes a high-side transistor 13 and a low-side transistor 14. The gate protection circuit 10, which includes a Zener diode 11 and a resistor 12, protects the gate of the high-side transistor 13. The level shift circuit 8 included in the high-withstand voltage driver 26, which includes thick-film gate P-type MOS transistors 15 and 16 and thin-film gate N-type MOS transistors 17 and 18, drives the high-side transistor 13.

The pre-driver circuit 7, which includes an inverter 31 and a NOR circuit 35, drives the high-withstand voltage driver 26 and the low-side transistor 14 in accordance with a signal which is input from a low-withstand voltage control section (not shown) to the control input terminal 5, to charge and discharge a load capacity 19. Note that an output terminal 4 of the high-withstand voltage output circuit 9 is connected to a common connection terminal of the high-side transistor 13 and the low-side transistor 14. A reference power supply terminal 1 is a terminal having a reference potential. A low-voltage power supply terminal 2 is a terminal of a low-voltage power supply of about 5 V. A high-voltage power supply terminal 3 is a terminal of a high-voltage power supply of 100 V or more. Input signals from the low-withstand voltage control section (not shown) are input through the control input terminals 5 and 6 to the pre-driver 7. The level shift circuit 8, the high-side transistor 13, and the low-side transistor 14 are forced to go to the high-impedance state, via the delay line 20, the HIZ fixing circuit 21, and the pre-driver circuit 7, in accordance with a signal which is input to the control input terminal 6 irrespective of the state of the control input terminal 5. The high-side transistor 13 is used to output a high level, and the low-side transistor 14 is used to output a low level.

The delay line 20 includes a plurality of inverters 31 and a NAND circuit 32. By using the NAND circuit 32, a delay is prevented when the high-side transistor 13 and the low-side transistor 14 return from the forced high-impedance state. The HIZ fixing circuit 21 includes an AND circuit 33.

Next, an operation of the output circuit including the high-withstand voltage driver 26 in the thus-configured multi-channel capacitive load drive circuit of the second embodiment of the present invention, will be described.

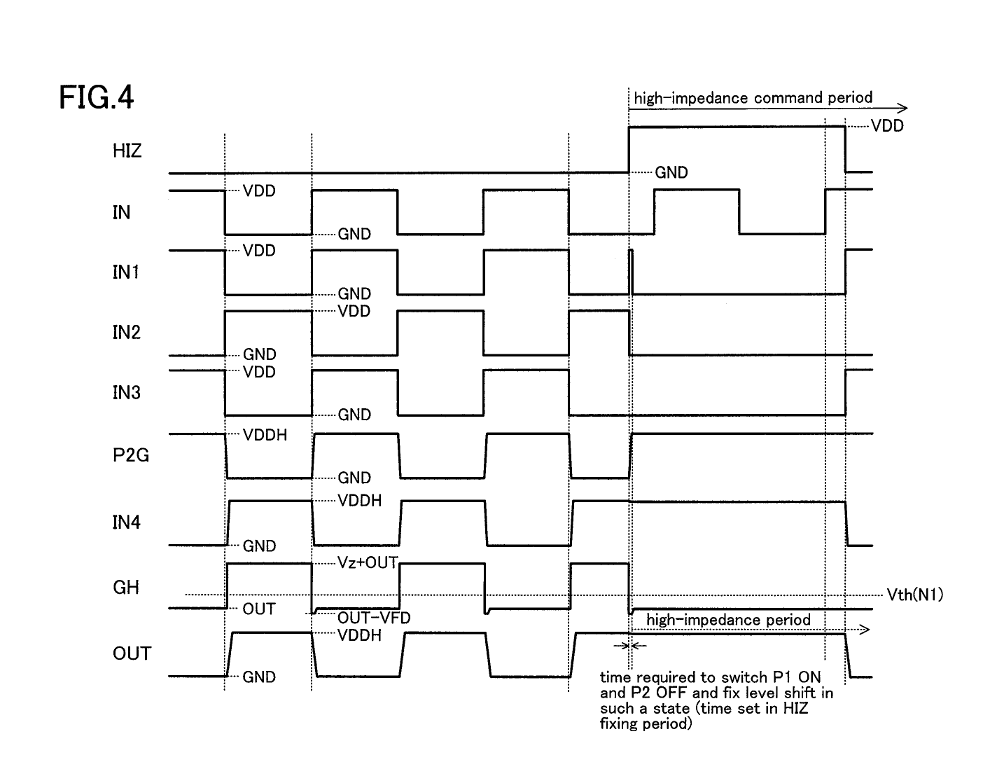

FIG. 4 is a timing diagram for describing the operation of the output circuit including the high-withstand voltage driver 26 in the multi-channel capacitive load drive circuit of the second embodiment of the present invention.

FIG. 4 shows an input signal HIZ which is input from the low-withstand voltage control section to the control input terminal 6, an input signal IN which is input from the low-withstand voltage control section to the control input terminal 5, an output signal IN2 of the pre-driver circuit 7 which is used to drive the level shift circuit 8 in accordance with the input signal IN and the input signal HIZ, an output signal IN1 of the HIZ fixing circuit 21, an output signal IN3 of the pre-driver circuit 7 which is used to drive the low-side transistor 14 in accordance with the input signal IN and the input signal HIZ, output signals P2G and IN4 of the level shift circuit 8 which are used to drive the high-side transistor 13 in accordance with the output signal IN1 of the HIZ fixing circuit 21 which is obtained by an AND operation of an output signal IN1′ of the pre-driver circuit 7 and an output signal DHIZ which is the input signal HIZ delayed by the delay line 20 only when the input signal HIZ is at the H level, a gate-source voltage GH of the high-side transistor 13 which is determined by the gate protection circuit 10 which has received the output signal IN4 of the level shift circuit 8, and an output voltage waveform OUT of the high-withstand voltage output circuit 9 which is output in accordance with the output signal IN3 of the pre-driver circuit 7.

Here, a case where a signal having the GND level is input to the control input terminal 6, so that the input signal HIZ goes to the L level (GND), will be described.

In this case, the output signal DHIZ of the delay line 20 immediately goes to the H level (VDD) without an influence of the delay line 20, so that the HIZ fixing circuit 21 can output the output signal IN1 having the same logical value as that of the output signal IN1′.

In this case, initially, when a signal having the GND level is input to the input terminal 5, so that the input signal IN goes to the L level (GND), then the output signal IN1′ goes to the L level (GND), and therefore, the output signal IN1 also goes to the L level (GND). Also, the output signal IN2 goes to the H level (VDD), the output signal P2G goes to the L level (GND), and the output signal IN4 goes to the H level (VDDH). Therefore, due to the Zener diode 11, the gate-source voltage GH becomes OUT+Vz (breakdown voltage), which is higher than or equal to the threshold voltage Vth (N1) of the high-side transistor 13, so that the high-side transistor 13 is switched ON. Also, the output signal IN3 goes to the L level (GND), so that the low-side transistor 14 is switched OFF. As a result, the output voltage waveform OUT goes to the H level (VDDH).

Next, when a signal having the VDD level is input to the input terminal 5, so that the input terminal IN goes to the H level (VDD), then the output signal IN1′ goes to the H level (VDD), and therefore, the output signal IN1 also goes to the H level (VDD). Also, the output signal IN2 goes to the L level (GND), the output signal P2G goes to the H level (VDDH), and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (N1) of the high-side transistor 13, and therefore, the high-side transistor 13 is switched OFF. Thereafter, the gate-source voltage GH returns to the same potential as that of the output terminal 4 due to the resistor 12. Also, the output signal IN3 goes to the H level (VDD), so that the low-side transistor 14 is switched ON. As a result, the output voltage waveform OUT goes to the L level (GND).

On the other hand, a case where a signal having the VDD level is input to the control input terminal 6 so as to cause the output terminal 4 to go to the high-impedance state, will be described.

In this case, when the input signal HIZ is at the H level (VDD), then the output signal IN1′ of the pre-driver circuit 7 goes to the H level (VDD), and the output signal DHIZ of the delay line 20 is initially at the H level (VDD) due to a delay, so that the HIZ fixing circuit 21 outputs the output signal IN1 having the same logical value as that of the output signal IN1′. Therefore, the output signal IN1 goes to the H level (VDD). Also, the output signal IN2 goes to the L level (GND), the output signal P2G goes to the H level (VDDH), and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (N1) of the gate of the high-side transistor 13. As a result, the high-side transistor 13 is switched OFF.

In this case, since the thin-film gate N-type MOS transistor 18 is switched ON, a load current flows in from the output terminal 4 via the Zener diode 11. Therefore, the output voltage waveform OUT gradually decreases toward the L level (GND). However, since the output of the delay line 20 goes to the L level (GND) after a predetermined time has passed, the output signal IN1 goes to the L level (GND). Therefore, the thin-film gate N-type MOS transistor 18 is switched OFF, so that a path through which the load current flows in from the output terminal 4 via the Zener diode 11 is interrupted. As a result, the output terminal 4 goes to the high-impedance state.

Here, the predetermined time by which a signal is delayed in the delay circuit 20 may be a time which allows the high-side transistor 13 to be completely switched OFF and the output signal P2G of the level shift circuit 8 to go to the H level (VDDH), so that the thick-film gate P-type MOS transistor 16 is latched at the OFF state. This time is typically sufficient when it is of the order of several hundreds of nanoseconds, and the thin-film gate N-type MOS transistor 18 has a size which is smaller by two or more orders of magnitude than that of the low-side transistor 14 which rapidly discharges the load capacity 19. Therefore, the potential of the output voltage waveform OUT goes to the high-impedance state with substantially no change. In addition, since the delay line 20 includes the NAND circuit 32, a delay by the inverters 31 does not occur when the input signal HIZ goes from the H level to the L level. Therefore, the potential of the output voltage waveform OUT can immediately return from the high impedance state.

### Third Embodiment

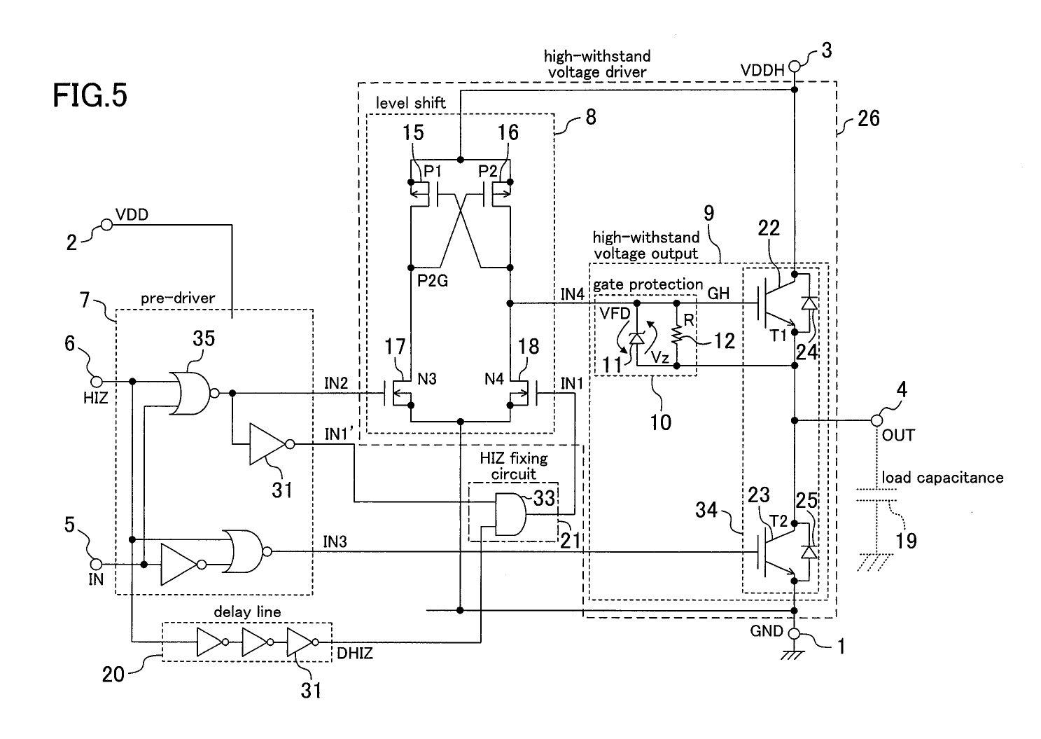

FIG. 5 shows an exemplary circuit configuration of an output circuit including a high-withstand voltage driver in a multi-channel capacitive load drive circuit according to a third embodiment of the present invention.

The output circuit of FIG. 5 includes a high-withstand voltage driver 26, a pre-driver circuit 7, a delay line 20, and an HIZ fixing circuit 21. The high-withstand voltage driver 26 includes a high-withstand voltage output circuit 9 and a level shift circuit 8.

The high-withstand voltage output circuit 9 included in the high-withstand voltage driver 26 includes a half-bridge circuit 34 and a gate protection circuit 10. The half-bridge circuit 34 includes a high-side transistor 22 and a high-side recirculating diode 24 connected in parallel with the high-side transistor 22, and a low-side transistor 23 and a low-side recirculating diode 25 connected in parallel with the low-side transistor 23. The gate protection circuit 10, which includes a Zener diode 11 and a resistor 12, protects the gate of the high-side transistor 22. The level shift circuit 8 included in the high-withstand voltage driver 26, which includes thick-film gate P-type MOS transistors 15 and 16 and thin-film gate N-type MOS transistors 17 and 18, drives the high-side transistor 22.

The pre-driver circuit 7, which includes an inverter 31 and a NOR circuit 35, drives the high-withstand voltage driver 26 and the low-side transistor 23 in accordance with a signal which is input from a low-withstand voltage control section (not shown) to the control input terminal 5, to charge and discharge a load capacity 19. Note that an output terminal 4 of the high-withstand voltage output circuit 9 is connected to a common connection terminal of the high-side transistor 22 and the low-side transistor 23. A reference power supply terminal 1 is a terminal having a reference potential. A low-voltage power supply terminal 2 is a terminal of a low-voltage power supply of about 5 V. A high-voltage power supply terminal 3 is a terminal of a high-voltage power supply of 100 V or more. Input signals from the low-withstand voltage control section (not shown) are input through the control input terminals 5 and 6 to the pre-driver 7. The level shift circuit 8, the high-side transistor 22, and the low-side transistor 23 are forced to go to the high-impedance state, via the delay line 20, the HIZ fixing circuit 21, and the pre-driver circuit 7, in accordance with a signal which is input to the control input terminal 6 irrespective of the state of the control input terminal 5. The high-side transistor 22 is used to output a high level, and the low-side transistor 23 is used to output a low level.

The delay line 20 includes a plurality of inverters 31. The HIZ fixing circuit 21 includes an AND circuit 33.

Next, an operation of the output circuit including the high-withstand voltage driver 26 in the thus-configured multi-channel capacitive load drive circuit of the third embodiment of the present invention will be described.

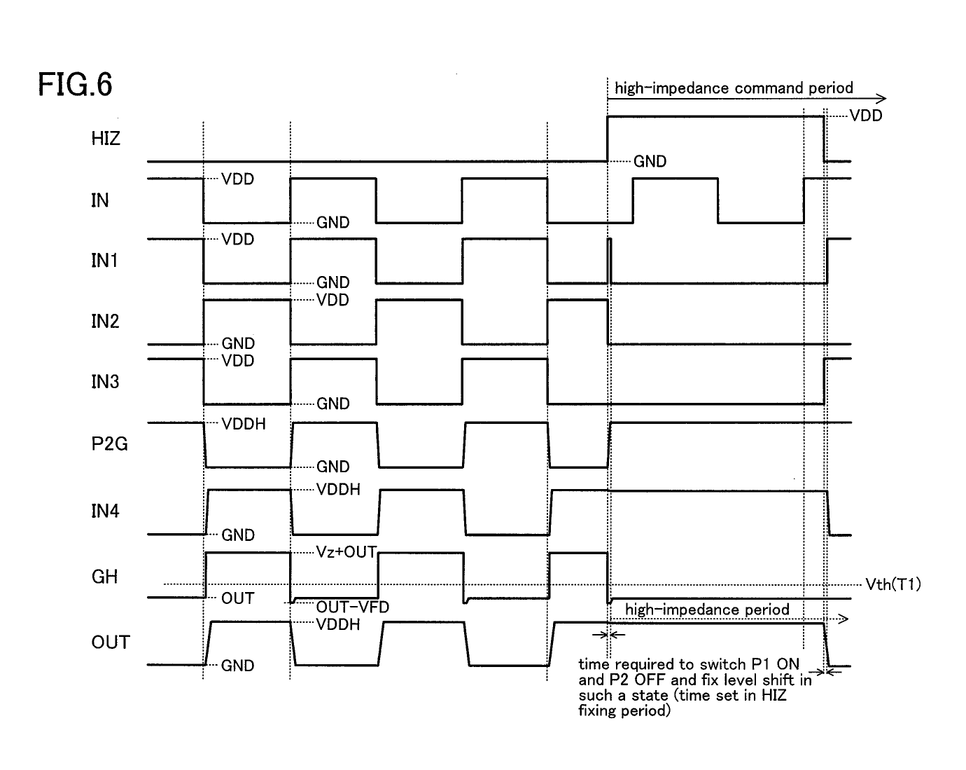

FIG. 6 is a timing diagram for describing the operation of the output circuit including the high-withstand voltage driver 26 in the multi-channel capacitive load drive circuit of the third embodiment of the present invention.

FIG. 6 shows an input signal HIZ which is input from the low-withstand voltage control section to the control input terminal 6, an input signal IN which is input from the low-withstand voltage control section to the control input terminal 5, an output signal IN2 of the pre-driver circuit 7 which is used to drive the level shift circuit 8 in accordance with the input signal IN and the input signal HIZ, an output signal IN1 of the HIZ fixing circuit 21, an output signal IN3 of the pre-driver circuit 7 which is used to drive the low-side transistor 23 in accordance with the input signal IN and the input signal HIZ, output signals P2G and IN4 of the level shift circuit 8 which are used to drive the high-side transistor 22 in accordance with the output signal IN1 of the HIZ fixing circuit 21 which is obtained by an AND operation of an output signal IN1′ of the pre-driver circuit 7 and an output signal DHIZ which is the input signal HIZ delayed by the delay line 20, a gate-source voltage GH of the high-side transistor 22 which is determined by the gate protection circuit 10 which has received the output signal IN4 of the level shift circuit 8, and an output voltage waveform OUT of the high-withstand voltage output circuit 9 which is output in accordance with the output signal IN3 of the pre-driver circuit 7.

Here, a case where a signal having the GND level is input to the control input terminal 6, so that the input signal HIZ goes to the L level (GND), will be described.

In this case, the output signal DHIZ of the delay line 20 goes to the H level (VDD), so that the HIZ fixing circuit 21 can output the output signal IN1 having the same logical value as that of the output signal IN1′.

In this case, initially, when a signal having the GND level is input to the input terminal 5, so that the input signal IN goes to the L level (GND), then the output signal IN1′ goes to the L level (GND), and therefore, the output signal IN1 also goes to the L level (GND). Also, the output signal IN2 goes to the H level (VDD), the output signal P2G goes to the L level (GND), and the output signal IN4 goes to the H level (VDDH). Therefore, due to the Zener diode 11, the gate-source voltage GH becomes OUT+Vz (breakdown voltage), which is higher than or equal to the threshold voltage Vth (T1) of the high-side transistor 22, so that the high-side transistor 22 is switched ON. Also, the output signal IN3 goes to the L level (GND), so that the low-side transistor 23 is switched OFF. As a result, the output voltage waveform OUT goes to the H level (VDDH).

Next, when a signal having the VDD level is input to the input terminal 5, so that the input terminal IN goes to the H level (VDD), then the output signal IN1′ goes to the H level (VDD), and therefore, the output signal IN1 also goes to the H level (VDD). Also, the output signal IN2 goes to the L level (GND), the output signal P2G goes to the H level (VDDH), and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (T1) of the high-side transistor 22, and therefore, the high-side transistor 22 is switched OFF. Thereafter, the gate-source voltage GH returns to the same potential as that of the output terminal 4 due to the resistor 12. Also, the output signal IN3 goes to the H level (VDD), so that the low-side transistor 23 is switched ON. As a result, the output voltage waveform OUT goes to the L level (GND).

On the other hand, a case where a signal having the VDD level is input to the control input terminal 6 so as to cause the output terminal 4 to go to the high-impedance state, will be described.

In this case, when the input signal HIZ is at the H level (VDD), then the output signal IN1′ of the pre-driver circuit 7 goes to the H level (VDD), and the output signal DHIZ of the delay line 20 is initially at the H level (VDD) due to a delay, so that the HIZ fixing circuit 21 outputs the output signal IN1 having the same logical value as that of the output signal IN1′. Therefore, the output signal IN1 goes to the H level (VDD). Also, the output signal IN2 goes to the L level (GND), the output signal P2G goes to the H level (VDDH), and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (T1) of the gate of the high-side transistor 22. As a result, the high-side transistor 22 is switched OFF.

In this case, since the thin-film gate N-type MOS transistor 18 is switched ON, a load current flows in from the output terminal 4 via the Zener diode 11. Therefore, the output voltage waveform OUT gradually decreases toward the L level (GND). However, since the output of the delay line 20 goes to the L level (GND) after a predetermined time has passed, the output signal IN1 goes to the L level (GND). Therefore, the thin-film gate N-type MOS transistor 18 is switched OFF, so that a path through which the load current flows in from the output terminal 4 via the Zener diode 11 is interrupted. As a result, the output terminal 4 goes to the high-impedance state.

Here, the predetermined time by which a signal is delayed in the delay circuit 20 may be a time which allows the high-side transistor 22 to be completely switched OFF and the output signal P2G of the level shift circuit 8 to go to the H level (VDDH), so that the thick-film gate P-type MOS transistor 16 is latched at the OFF state. This time is typically sufficient when it is of the order of several hundreds of nanoseconds, and the thin-film gate N-type MOS transistor 18 has a size which is smaller by two or more orders of magnitude than that of the low-side transistor 23 which rapidly discharges the load capacity 19. Therefore, the potential of the output voltage waveform OUT goes to the high-impedance state with substantially no change.

### Fourth Embodiment

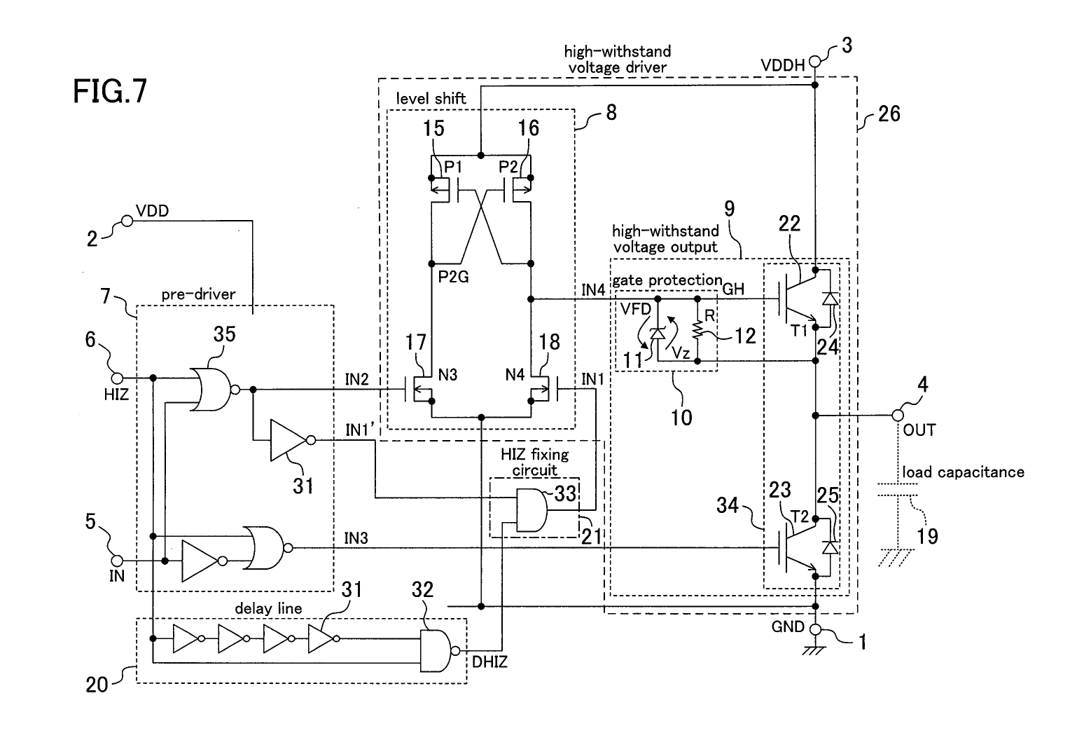

FIG. 7 shows an exemplary circuit configuration of an output circuit including a high-withstand voltage driver in a multi-channel capacitive load drive circuit according to a fourth embodiment of the present invention.

The output circuit of FIG. 7 includes a high-withstand voltage driver 26, a pre-driver circuit 7, a delay line 20, and an HIZ fixing circuit 21. The high-withstand voltage driver 26 includes a high-withstand voltage output circuit 9 and a level shift circuit 8.

The high-withstand voltage output circuit 9 included in the high-withstand voltage driver 26 includes a half-bridge circuit 34 and a gate protection circuit 10. The half-bridge circuit 34 includes a high-side transistor 22 and a high-side recirculating diode 24 connected in parallel with the high-side transistor 22, and a low-side transistor 23 and a low-side recirculating diode 25 connected in parallel with the low-side transistor 23. The gate protection circuit 10, which includes a Zener diode 11 and a resistor 12, protects the gate of the high-side transistor 22. The level shift circuit 8 included in the high-withstand voltage driver 26, which includes thick-film gate P-type MOS transistors 15 and 16 and thin-film gate N-type MOS transistors 17 and 18, drives the high-side transistor 22.

The pre-driver circuit 7, which includes an inverter 31 and a NOR circuit 35, drives the high-withstand voltage driver 26 and the low-side transistor 23 in accordance with a signal which is input from a low-withstand voltage control section (not shown) to the control input terminal 5, to charge and discharge a load capacity 19. Note that an output terminal 4 of the high-withstand voltage output circuit 9 is connected to a common connection terminal of the high-side transistor 22 and the low-side transistor 23. A reference power supply terminal 1 is a terminal having a reference potential. A low-voltage power supply terminal 2 is a terminal of a low-voltage power supply of about 5 V. A high-voltage power supply terminal 3 is a terminal of a high-voltage power supply of 100 V or more. Input signals from the low-withstand voltage control section (not shown) are input through the control input terminals 5 and 6 to the pre-driver 7. The level shift circuit 8, the high-side transistor 22, and the low-side transistor 23 are forced to go to the high-impedance state, via the delay line 20, the HIZ fixing circuit 21, and the pre-driver circuit 7, in accordance with a signal which is input to the control input terminal 6 irrespective of the state of the control input terminal 5. The high-side transistor 22 is used to output a high level, and the low-side transistor 23 is used to output a low level.

The delay line 20 includes a plurality of inverters 31 and a NAND circuit 32. By using the NAND circuit 32, a delay is prevented when the high-side transistor 22 and the low-side transistor 23 return from the forced high-impedance state. The HIZ fixing circuit 21 includes an AND circuit 33.

Next, an operation of the output circuit including the high-withstand voltage driver 26 in the thus-configured multi-channel capacitive load drive circuit of the fourth embodiment of the present invention will be described.

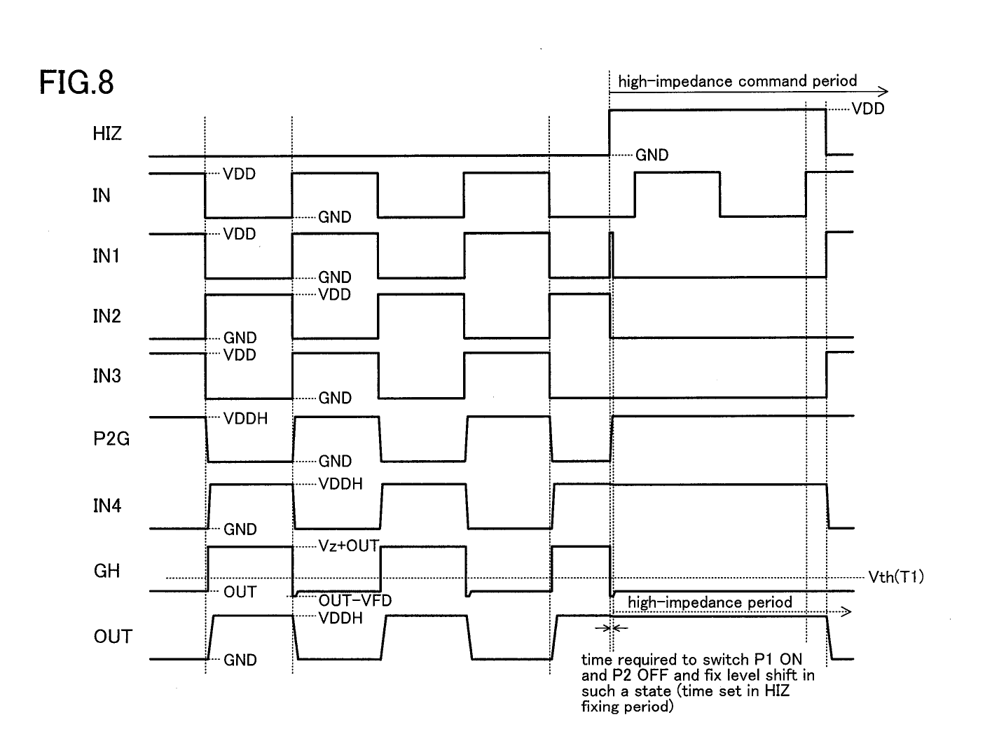

FIG. 8 is a timing diagram for describing the operation of the output circuit including the high-withstand voltage driver 26 in the multi-channel capacitive load drive circuit of the fourth embodiment of the present invention.

FIG. 8 shows an input signal HIZ which is input from the low-withstand voltage control section to the control input terminal 6, an input signal IN which is input from the low-withstand voltage control section to the control input terminal 5, an output signal IN2 of the pre-driver circuit 7 which is used to drive the level shift circuit 8 in accordance with the input signal IN and the input signal HIZ, an output signal IN1 of the HIZ fixing circuit 21, an output signal IN3 of the pre-driver circuit 7 which is used to drive the low-side transistor 23 in accordance with the input signal IN and the input signal HIZ, output signals P2G and IN4 of the level shift circuit 8 which are used to drive the high-side transistor 22 in accordance with the output signal IN1 of the HIZ fixing circuit 21 which is obtained by an AND operation of an output signal IN1′ of the pre-driver circuit 7 and an output signal DHIZ which is the input signal HIZ delayed by the delay line 20 only when the input signal HIZ is at the H level, a gate-source voltage GH of the high-side transistor 22 which is determined by the gate protection circuit 10 which has received the output signal IN4 of the level shift circuit 8, and an output voltage waveform OUT of the high-withstand voltage output circuit 9 which is output in accordance with the output signal IN3 of the pre-driver circuit 7.

Here, a case where a signal having the GND level is input to the control input terminal 6, so that the input signal HIZ goes to the L level (GND), will be described.

In this case, the output signal DHIZ of the delay line 20 immediately goes to the H level (VDD) without an influence of the delay line 20, so that the HIZ fixing circuit 21 can output the output signal IN1 having the same logical value as that of the output signal IN1′.

In this case, initially, when a signal having the GND level is input to the input terminal 5, so that the input signal IN goes to the L level (GND), then the output signal IN1′ goes to the L level (GND), and therefore, the output signal IN1 also goes to the L level (GND). Also, the output signal IN2 goes to the H level (VDD), the output signal P2G goes to the L level (GND), and the output signal IN4 goes to the H level (VDDH). Therefore, due to the Zener diode 11, the gate-source voltage GH becomes OUT+Vz (breakdown voltage), which is higher than or equal to the threshold voltage Vth (T1) of the high-side transistor 22, so that the high-side transistor 22 is switched ON. Also, the output signal IN3 goes to the L level (GND), so that the low-side transistor 23 is switched OFF. As a result, the output voltage waveform OUT goes to the H level (VDDH).

Next, when a signal having the VDD level is input to the input terminal 5, so that the input terminal IN goes to the H level (VDD), then the output signal IN1′ goes to the H level (VDD), and therefore, the output signal IN1 also goes to the H level (VDD). Also, the output signal IN2 goes to the L level (GND), the output signal P2G goes to the H level (VDDH), and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (T1) of the high-side transistor 22, and therefore, the high-side transistor 22 is switched OFF. Thereafter, the gate-source voltage GH returns to the same potential as that of the output terminal 4 due to the resistor 12. Also, the output signal IN3 goes to the H level (VDD), so that the low-side transistor 23 is switched ON. As a result, the output voltage waveform OUT goes to the L level (GND).

On the other hand, a case where a signal having the VDD level is input to the control input terminal 6 so as to cause the output terminal 4 to go to the high-impedance state, will be described.

In this case, when the input signal HIZ is at the H level (VDD), then the output signal IN1′ of the pre-driver circuit 7 goes to the H level (VDD), and the output signal DHIZ of the delay line 20 is initially at the H level (VDD) due to a delay, so that the HIZ fixing circuit 21 outputs the output signal IN1 having the same logical value as that of the output signal IN1′. Therefore, the output signal IN1 goes to the H level (VDD). Also, the output signal IN2 goes to the L level (GND), the output signal P2G goes to the H level (VDDH), and the output signal IN4 goes to the L level (GND). Therefore, the Zener diode 11 is forward-biased, so that the gate-source voltage GH becomes OUT-VFD (Zener forward voltage), which is lower than or equal to the threshold voltage Vth (T1) of the gate of the high-side transistor 22. As a result, the high-side transistor 22 is switched OFF.

In this case, since the thin-film gate N-type MOS transistor 18 is switched ON, a load current flows in from the output terminal 4 via the Zener diode 11. Therefore, the output voltage waveform OUT gradually decreases toward the L level (GND). However, since the output of the delay line 20 goes to the L level (GND) after a predetermined time has passed, the output signal IN1 goes to the L level (GND). Therefore, the thin-film gate N-type MOS transistor 18 is switched OFF, so that a path through which the load current flows in from the output terminal 4 via the Zener diode 11 is interrupted. As a result, the output terminal 4 goes to the high-impedance state.

Here, the predetermined time by which a signal is delayed in the delay circuit 20 may be a time which allows the high-side transistor 22 to be completely switched OFF and the output signal P2G of the level shift circuit 8 to go to the H level (VDDH), so that the thick-film gate P-type MOS transistor 16 is latched at the OFF state. This time is typically sufficient when it is of the order of several hundreds of nanoseconds, and the thin-film gate N-type MOS transistor 18 has a size which is smaller by two or more orders of magnitude than that of the low-side transistor 23 which rapidly discharges the load capacity 19. Therefore, the potential of the output voltage waveform OUT goes to the high-impedance state with substantially no change. In addition, since the delay line 20 includes the NAND circuit 32, a delay by the inverters 31 does not occur when the input signal HIZ goes from the H level to the L level. Therefore, the potential of the output voltage waveform OUT can immediately return from the high impedance state.

### Fifth Embodiment

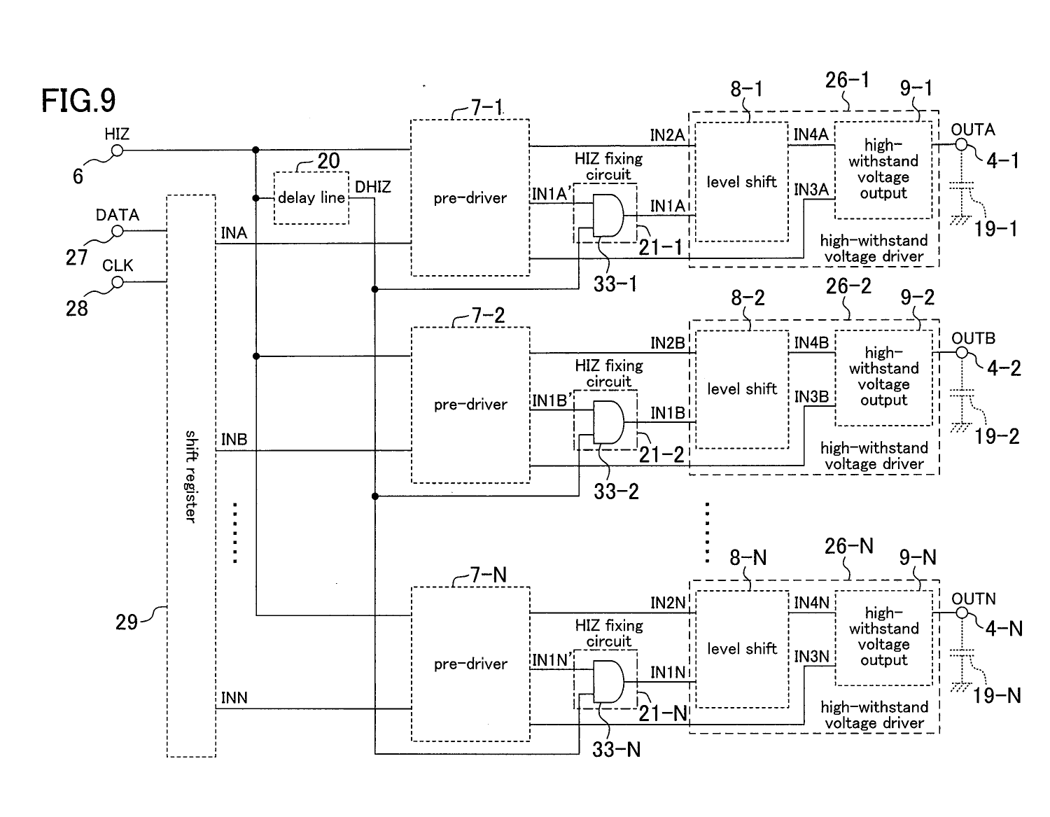

FIG. 9 shows an exemplary circuit configuration of a multi-channel capacitive load drive circuit according to a fifth embodiment of the present invention. The multi-channel capacitive load drive circuit of FIG. 9 includes a plurality of output circuits which are those described above with reference to FIGS. 1 to 8. Specifically, the multi-channel capacitive load drive circuit of FIG. 9 includes a plurality of high-withstand voltage drivers, a plurality of pre-driver circuits, a plurality of HIZ fixing circuits, and a single delay line 20. The multi-channel capacitive load drive circuit of FIG. 9 further includes a shift register 29 for successively outputting outputs of the output circuits. The shift register 29 is connected to a DATA input terminal 27 and a CLK input terminal 28.

As shown in FIG. 9, the high-withstand voltage drivers 26-1 to 26-N include high-withstand voltage output circuits 9-1 to 9-N and level shift circuits 8-1 to 8-N for pre-driving the high-withstand voltage outputs 9-1 to 9-N, respectively. The pre-driver circuits 7-1 to 7-N drive the high-withstand voltage driver groups 26-1 to 26-N in accordance with control signals INA to INN from the shift register 29 and a control signal from the control signal input terminal 6 to charge and discharge load capacity groups 19-1 to 19-N, respectively. Here, the level shift circuits 8-1 to 8-N and the high-withstand voltage output circuits 9-1 to 9-N are forced to go to the high-impedance state, via a delay line 20, the HIZ fixing circuits 21-1 to 21-N, and the pre-driver circuits 7-1 to 7-N, in accordance with a signal which is input to the control signal input terminal 6 irrespective of the states of the control signals INA to INN from the shift register 29. Note that output terminals 4-1 to 4-N are connected to the high-withstand voltage outputs 9-1 to 9-N, respectively.

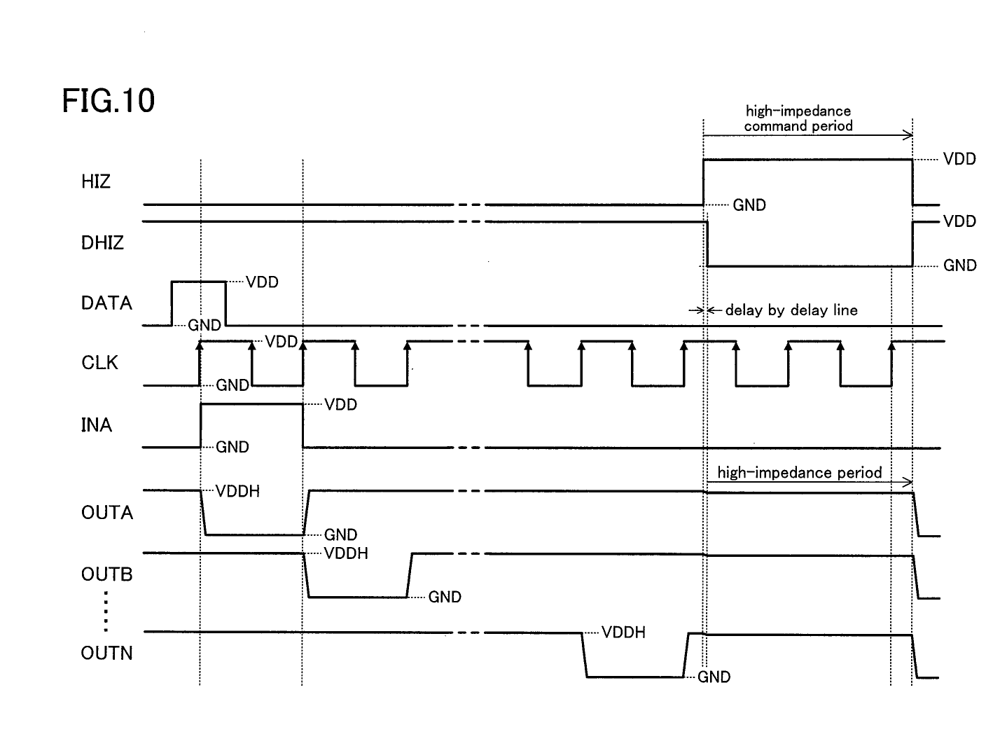

FIG. 10 is a timing diagram for describing an operation of a multi-output circuit including the high-withstand voltage drivers in the multi-channel capacitive load drive circuit of the fifth embodiment of the present invention.

FIG. 10 shows an input signal HIZ which is input from a low-withstand voltage control section to the control input terminal 6, a clock signal CLK which is input to a CLK input terminal 28, a data signal DATA of the shift register 29 which is input to a DATA input terminal 27, a control signal INA from the shift register 29, an output signal DHIZ which is the input signal HIZ delayed by the delay line 20, and output voltage waveforms OUTA to OUTN of the high-withstand voltage drivers 26-1 to 26-N, respectively.

Here, a case where a signal having the GND level is input to the control input terminal 6, so that the input signal HIZ is at the L level (GND), will be described.

In this case, the output signal DHIZ of the delay line 20 goes to the H level (VDD), so that the HIZ fixing circuits 21-1 to 21-N can output output signals IN1A to IN1N having the same logical values as those of output signal IN1A′ to IN1N′ of the pre-drivers 7-1 to 7-N, respectively.

Initially, if the clock signal CLK goes from the L level (GND) to the H level (VDD) when the data signal DATA having the H level (VDD) is input to the shift register 29, then the input signal INA goes to the H level (VDD) and the output voltage OUTA goes to the L level (GND). Next, if the clock signal CLK goes from the H level (VDD) to the L level (GND) when the data signal DATA having the L level (GND) is input to the shift register 29, then the input signal INA goes to the L level (GND), the output voltage waveform OUTA goes to the H level (VDDH), and then the input signal INB goes to the H level (VDD), and the output voltage waveform OUTB goes to the L level (GND).

Thereafter, the output voltage waveform OUT is successively changed in synchronization with the clock signal CLK until INN.

On the other hand, a case where a signal having the VDD level is input to the control input terminal 6 so as to cause the output terminals 4-1 to 4-N to go to the high impedance state, will be described.

In this case, when the input signal HIZ is at the H level (VDD), the output signals IN1A′ to IN1N′ of the pre-driver circuits 7-1 to 7-N go to the H level (VDD) and the output signal DHIZ of the delay line 20 is initially at the H level (VDD) due to a delay, so that the HIZ fixing circuits 21-1 to 21-N output the output signals IN1A to IN1N having the same logical values as those of the output signals N1A′ to IN1N′, respectively. Therefore, the output signals IN1A to IN1N go to the H level (VDD). Also, output signals IN2A to IN2N go to the L level (GND), so that output signals IN4A to IN4N go to the L level (GND). As a result, the high-withstand voltage outputs 9-1 to 9-N attempt to go to the L level (GND). However, due to the delay line 20, after a predetermined time of the order of several hundreds of nanoseconds has passed, the level shift circuits 8-1 to 8-N go to the high impedance state, so that the output terminals 4-1 to 4-N go to the high impedance state.

### Sixth Embodiment

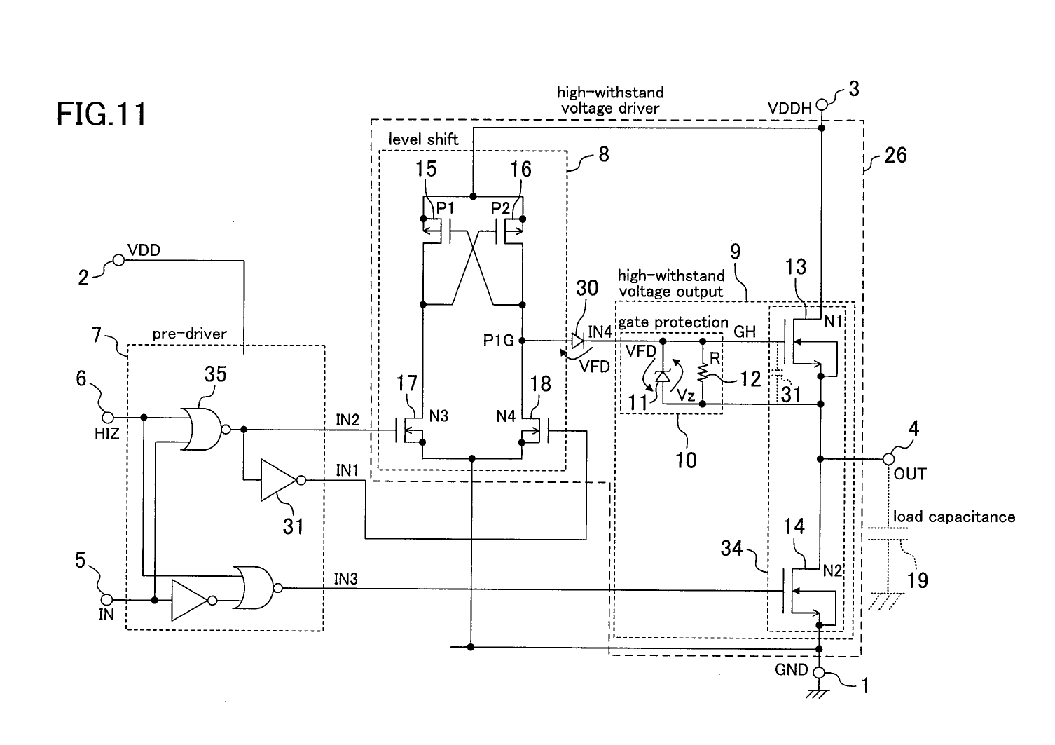

FIG. 11 shows an exemplary circuit configuration of an output circuit including a high-withstand voltage driver in a multi-channel capacitive load drive circuit according to a sixth embodiment of the present invention.

The output circuit of FIG. 11 includes a high-withstand voltage driver 26 having a high-withstand voltage output circuit 9 and a level shift circuit 8, and a pre-driver circuit 7. The output circuit further includes a high-withstand voltage diode 30 between the high-withstand voltage output circuit 9 and the level shift circuit 8. The high-withstand voltage diode 30 passes a current when a signal which switches ON the high-side transistor 13 is input from the level shift circuit 8, and interrupts a current when a signal which switches OFF the high-side transistor 13 is input from the level shift circuit 8.

The high-withstand voltage output circuit 9 included in the high-withstand voltage driver 26 includes a half-bridge circuit 34 and a gate protection circuit 10. The half-bridge circuit 34 includes a high-side transistor 13 and a low-side transistor 14. The gate protection circuit 10, which includes a Zener diode 11 and a resistor 12, protects the gate of the high-side transistor 13. The level shift circuit 8 included in the high-withstand voltage driver 26, which includes thick-film gate P-type MOS transistors 15 and 16 and thin-film gate N-type MOS transistors 17 and 18, drives the high-side transistor 13.

The pre-driver circuit 7, which includes an inverter 31 and a NOR circuit 35, drives the high-withstand voltage driver 26 and the low-side transistor 14 in accordance with a signal which is input to the control input terminal 5 from a low-withstand voltage control section (not shown), to charge and discharge a load capacity 19. Note that an output terminal 4 of the high-withstand voltage output circuit 9 is connected to a common connection terminal of the high-side transistor 13 and the low-side transistor 14. A reference power supply terminal 1 is a terminal having a reference potential. A low-voltage power supply terminal 2 is a terminal of a low-voltage power supply of about 5 V. A high-voltage power supply terminal 3 is a terminal of a high-voltage power supply of 100 V or more. Input signals from the low-withstand voltage control section (not shown) are input through the control input terminals 5 and 6 to the pre-driver 7. The level shift circuit 8, the high-side transistor 13, and the low-side transistor 14 are forced to go to the high-impedance state, via the pre-driver circuit 7, in accordance with a signal which is input to the control input terminal 6 irrespective of the state of the control input terminal 5. The high-side transistor 13 is used to output a high level, and the low-side transistor 14 is used to output a low level.

Next, an operation of the output circuit including the high-withstand voltage driver 26 in the thus-configured multi-channel capacitive load drive circuit of the sixth embodiment of the present invention will be described.

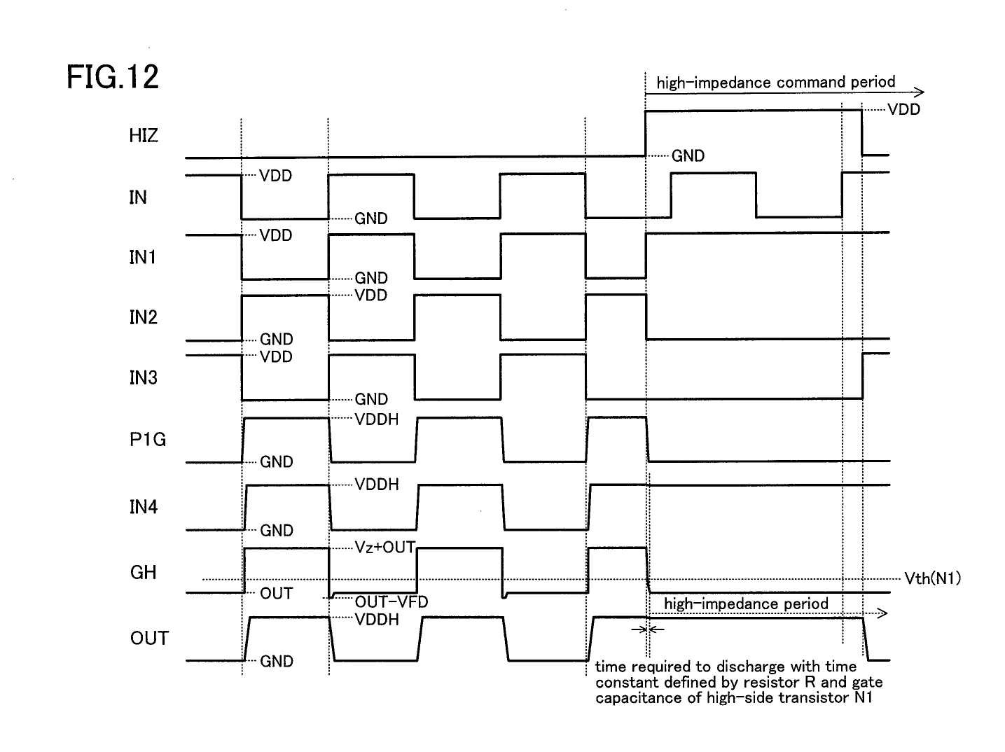

FIG. 12 is a timing diagram for describing the operation of the output circuit including the high-withstand voltage driver 26 in the multi-channel capacitive load drive circuit of the sixth embodiment of the present invention.

FIG. 12 shows an input signal HIZ which is input from the low-withstand voltage control section to the control input terminal 6, an input signal IN which is input from the low-withstand voltage control section to the control input terminal 5, output signals IN1 and IN2 of the pre-driver circuit 7 which are used to drive the level shift circuit 8 in accordance with the input signal IN and the input signal HIZ, an output signal IN3 of the pre-driver circuit 7 which is used to drive the low-side transistor 14 in accordance with the input signal IN and the input signal HIZ, an output signal PIG (an anode-side input signal of the high-withstand voltage diode 30) of the level shift circuit 8 which is used to drive the high-side transistor 13 in accordance with the output signals IN1 and IN2, a cathode-side input signal IN4 of the high-withstand voltage diode 30, a gate-source voltage GH of the high-side transistor 13 which is determined by the gate protection circuit 10 which has received the cathode-side output signal IN4 of the high-withstand voltage diode 30, and an output voltage waveform OUT of the high-withstand voltage output circuit 9 which is output in accordance with the output signal IN3 of the pre-driver circuit 7.

Here, a case where a signal having the GND level is input to the control input terminal 6, so that the input signal HIZ is at the L level (GND), will be described.

In this case, when a signal having the GND level is input to the input terminal 5, so that the input signal IN goes to the L level (GND), then the output signal IN1 goes to the L level (GND) and the output signal IN2 goes to the H level (VDD). The output signal PIG then goes to the H level (VDDH). Therefore, the high-withstand voltage diode 30 is forward-biased, so that the output signal IN4 goes to the H level (VDDH-VFD (diode forward voltage)). Therefore, due to the Zener diode 11, the gate-source voltage GH becomes OUT+Vz (breakdown voltage), which is higher than or equal to the threshold voltage Vth (N1) of the high-side transistor 13, so that the high-side transistor 13 is switched ON. Also, the output signal IN3 goes to the L level (GND), so that the low-side transistor 14 is switched OFF. As a result, the output voltage waveform OUT goes to the H level (VDDH).

Next, when a signal having the VDD level is input to the input terminal 5, so that the input signal IN goes to the H level, then the output signal IN1 goes to the H level (VDD) and the output signal IN2 goes to the L level (GND), and therefore, the output signal PIG goes to the L level (GND). Therefore, the high-withstand voltage diode 30 is reverse-biased, so that the output signal IN4 is caused to have the same potential as that of the high-withstand voltage output terminal 4 due to the resistor 12. Therefore, the gate-source voltage GH also becomes 0 V, so that the gate of the high-side transistor 13 is caused to have a voltage which is lower than or equal to the threshold voltage Vth (N1), and therefore, the high-side transistor 13 is switched OFF. Also, the output signal IN3 goes to the H level (VDD), so that the low-side transistor 14 is switched ON. As a result, the output voltage waveform OUT goes to the L level (GND).

On the other hand, a case where a signal having the VDD level is input to the control input terminal 6 so as to cause the output terminal 4 to go to the high-impedance state, will be described.

In this case, when the input signal HIZ is at the H level (VDD), then the output signal IN1 of the pre-driver circuit 7 goes to the H level (VDD) and the output signal IN2 goes to the L level (GND), so that the output signal PIG goes to the L level (GND). Therefore, the high-withstand voltage diode 30 is reverse-biased, so that the output signal IN4 is caused to have the same potential as that of the high-withstand voltage output terminal 4 due to the resistor 12. Therefore, the gate-source voltage GH becomes 0 V, so that the gate of the high-side transistor 13 is caused to have a voltage which is lower than or equal to the threshold voltage Vth (N1), and therefore, the high-side transistor 13 is switched OFF. In this case, even if the thin-film gate N-type MOS transistor 18 is switched ON, since the high-withstand voltage diode 30 is reverse-biased, a path through which a load current flows in from the high-withstand voltage output terminal 4 via the Zener diode 11 is interrupted, so that the high-withstand voltage output terminal 4 goes to the high impedance.

### Seventh Embodiment

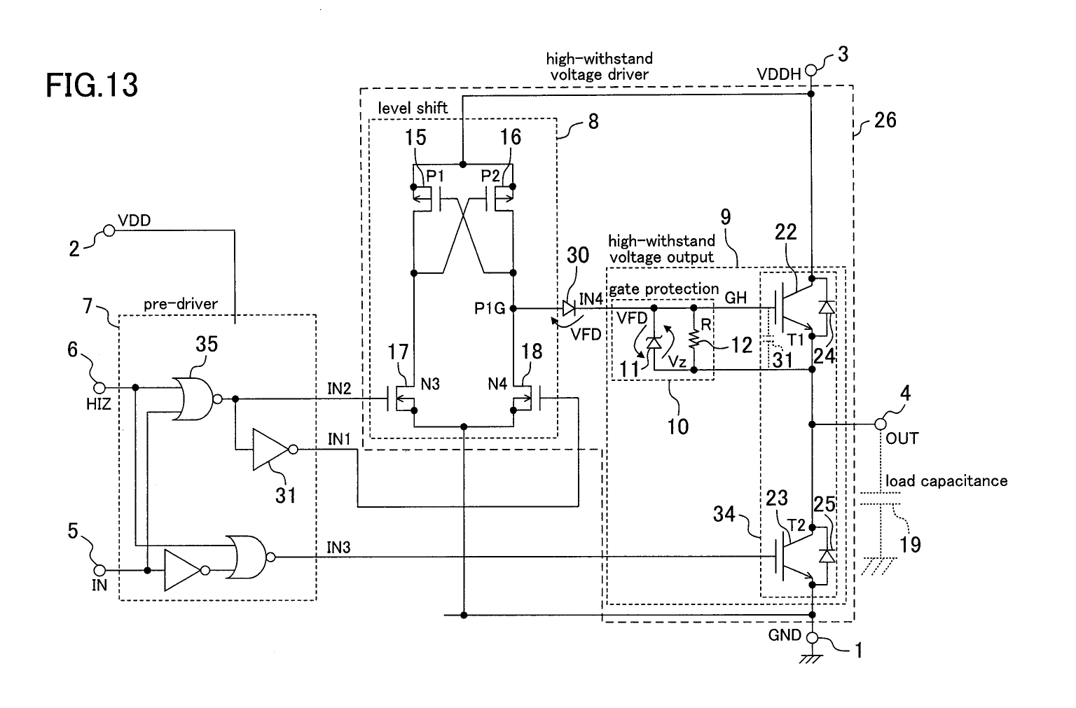

FIG. 13 shows an exemplary circuit configuration of an output circuit including a high-withstand voltage driver in a multi-channel capacitive load drive circuit according to a seventh embodiment of the present invention.

The output circuit of FIG. 13 includes a high-withstand voltage driver 26 having a high-withstand voltage output circuit 9 and a level shift circuit 8, and a pre-driver circuit 7. The output circuit further includes a high-withstand voltage diode 30 between the high-withstand voltage output circuit 9 and the level shift circuit 8. The high-withstand voltage diode 30 passes a current when a signal which switches ON the high-side transistor 13 is input from the level shift circuit 8, and interrupts a current when a signal which switches OFF the high-side transistor 13 is input from the level shift circuit 8.

The high-withstand voltage output circuit 9 included in the high-withstand voltage driver 26 includes a half-bridge circuit 34 and a gate protection circuit 10. The half-bridge circuit 34 includes a high-side transistor 22 and a high-side recirculating diode 24 connected in parallel with the high-side transistor 22, and a low-side transistor 23 and a low-side recirculating diode 25 connected in parallel with the low-side transistor 23. The gate protection circuit 10, which includes a Zener diode 11 and a resistor 12, protects the gate of the high-side transistor 22. The level shift circuit 8 included in the high-withstand voltage driver 26, which includes thick-film gate P-type MOS transistors 15 and 16 and thin-film gate N-type MOS transistors 17 and 18, drives the high-side transistor 22.

The pre-driver circuit 7, which includes an inverter 31 and a NOR circuit 35, drives the high-withstand voltage driver 26 and the low-side transistor 23 in accordance with a signal which is input to the control input terminal 5 from a low-withstand voltage control section (not shown), to charge and discharge a load capacity 19. Note that an output terminal 4 of the high-withstand voltage output circuit 9 is connected to a common connection terminal of the high-side transistor 22 and the low-side transistor 23. A reference power supply terminal 1 is a terminal having a reference potential. A low-voltage power supply terminal 2 is a terminal of a low-voltage power supply of about 5 V. A high-voltage power supply terminal 3 is a terminal of a high-voltage power supply of 100 V or more. Input signals from the low-withstand voltage control section (not shown) are input through the control input terminals 5 and 6 to the pre-driver 7. The level shift circuit 8, the high-side transistor 22, and the low-side transistor 23 are forced to go to the high-impedance state, via the pre-driver circuit 7, in accordance with a signal which is input to the control input terminal 6 irrespective of the state of the control input terminal 5. The high-side transistor 22 is used to output a high level, and the low-side transistor 23 is used to output a low level.

Next, an operation of the output circuit including the high-withstand voltage driver 26 in the thus-configured multi-channel capacitive load drive circuit of the seventh embodiment of the present invention, will be described.

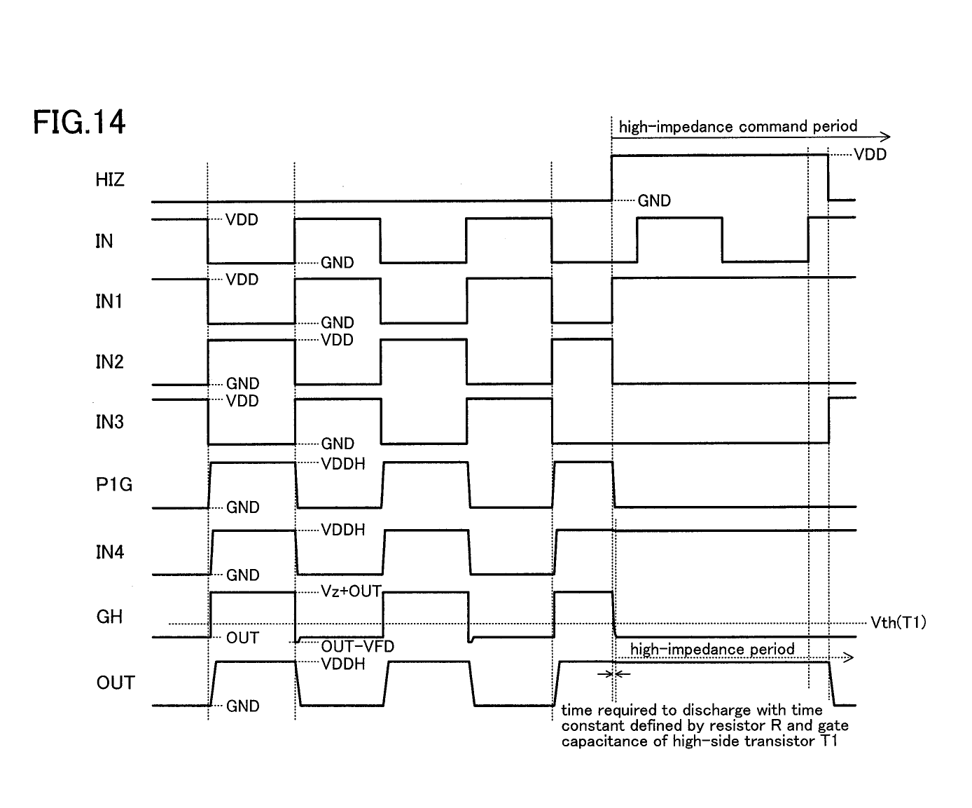

FIG. 14 is a timing diagram for describing the operation of the output circuit including the high-withstand voltage driver 26 in the multi-channel capacitive load drive circuit of the seventh embodiment of the present invention.

FIG. 14 shows an input signal HIZ which is input from the low-withstand voltage control section to the control input terminal 6, an input signal IN which is input from the low-withstand voltage control section to the control input terminal 5, output signals IN1 and IN2 of the pre-driver circuit 7 which are used to drive the level shift circuit 8 in accordance with the input signal IN and the input signal HIZ, an output signal IN3 of the pre-driver circuit 7 which is used to drive the low-side transistor 23 in accordance with the input signal IN and the input signal HIZ, an output signal P1G (an anode-side input signal of the high-withstand voltage diode 30) of the level shift circuit 8 which is used to drive the high-side transistor 22 in accordance with the output signals IN1 and IN2, a cathode-side input signal IN4 of the high-withstand voltage diode 30, a gate-source voltage GH of the high-side transistor 22 which is determined by the gate protection circuit 10 which has received the cathode-side output signal IN4 of the high-withstand voltage diode 30, and an output voltage waveform OUT of the high-withstand voltage output circuit 9 which is output in accordance with the output signal IN3 of the pre-driver circuit 7.

Here, a case where a signal having the GND level is input to the control input terminal 6, so that the input signal HIZ goes to the L level (GND), will be described.

In this case, when a signal having the GND level is input to the input terminal 5, so that the input signal IN goes to the L level (GND), then the output signal IN1 goes to the L level (GND) and the output signal IN2 goes to the H level (VDD). The output signal P1G then goes to the H level (VDDH). Therefore, the high-withstand voltage diode 30 is forward-biased, so that the output signal IN4 goes to the H level (VDDH-VFD (diode forward voltage)). Therefore, due to the Zener diode 11, the gate-source voltage GH becomes OUT+Vz (breakdown voltage), which is higher than or equal to the threshold voltage Vth (T1) of the high-side transistor 22, so that the high-side transistor 22 is switched ON. Also, the output signal IN3 goes to the L level (GND), so that the low-side transistor 23 is switched OFF. As a result, the output voltage waveform OUT goes to the H level (VDDH).

Next, when a signal having the VDD level is input to the input terminal 5, so that the input signal IN goes to the H level, then the output signal IN1 goes to the H level (VDD) and the output signal IN2 goes to the L level (GND), and therefore, the output signal P1G goes to the L level (GND). Therefore, the high-withstand voltage diode 30 is reverse-biased, so that the output signal IN4 is caused to have the same potential as that of the high-withstand voltage output terminal 4 due to the resistor 12. Therefore, the gate-source voltage GH also becomes 0 V, so that the gate of the high-side transistor 22 is caused to have a voltage which is lower than or equal to the threshold voltage Vth (T1), and therefore, the high-side transistor 22 is switched OFF. Also, the output signal IN3 goes to the H level (VDD), so that the low-side transistor 23 is switched ON. As a result, the output voltage waveform OUT goes to the L level (GND).

On the other hand, a case where a signal having the VDD level is input to the control input terminal 6 so as to cause the output terminal 4 to go to the high-impedance state, will be described.

In this case, when the input signal HIZ is at the H level (VDD), then the output signal IN1 of the pre-driver circuit 7 goes to the H level (VDD) and the output signal IN2 goes to the L level (GND), so that the output signal PIG goes to the L level (GND). Therefore, the high-withstand voltage diode 30 is reverse-biased, so that the output signal IN4 is caused to have the same potential as that of the high-withstand voltage output terminal 4 due to the resistor 12. Therefore, the gate-source voltage GH becomes 0 V, so that the gate of the high-side transistor 22 is caused to have a voltage which is lower than or equal to the threshold voltage Vth (T1), and therefore, the high-side transistor 22 is switched OFF. In this case, even if the thin-film gate N-type MOS transistor 18 is switched ON, since the high-withstand voltage diode 30 is reverse-biased, a path through which a load current flows in from the high-withstand voltage output terminal 4 via the Zener diode 11 is interrupted, so that the high-withstand voltage output terminal 4 goes to the high impedance.

The term “reference potential” as used herein refers to a potential connected to the substrate of the semiconductor chip, including potentials other than the ground potential as described in the embodiments above, though it typically means the ground potential.

Note that the present invention is useful for a multi-channel capacitive load drive circuit for driving a capacitive load, such as a PDP or the like.

What is claimed is:

1. An output circuit comprising:
a high-side transistor;
a low-side transistor;
a gate protection circuit for protecting a gate voltage of the high-side transistor;
a level shift circuit for driving the high-side transistor via the gate protection circuit; and
a pre-driver circuit for driving the level shift circuit and the low-side transistor,
wherein a connection point of the high-side transistor and the low-side transistor serves as an output terminal, and
the level shift circuit interrupts a current path from the output terminal to the level shift circuit after a predetermined time has passed since the high-side transistor was switched OFF.

2. The output circuit of claim 1, wherein
the level shift circuit goes to a high-impedance state after the high-side transistor is switched OFF, thereby interrupting the current path.

3. The output circuit of claim 1, further comprising:
a delay line including a plurality of inverters connected to each other in series, for setting the predetermined time.

4. The output circuit of claim 1, wherein the predetermined time is longer than a time required for the high-side transistor to be completely switched OFF.

5. The output circuit of claim 3, wherein
the delay line cancels the interruption of the current path without setting the predetermined time.

6. A multi-output circuit comprising:
a plurality of output circuits, wherein each output circuit is the output circuit of claim 1;
a shift register for successively outputting outputs of the output circuits; and
one or more delay lines each including a plurality of inverters connected to each other in series, for setting the predetermined times for the respective corresponding level shift circuits.

7. An output circuit comprising:
a high-side transistor;
a high-side recirculating diode connected in parallel with the high-side transistor;
a low-side transistor;
a low-side recirculating diode connected in parallel with the low-side transistor;
a gate protection circuit for protecting a gate voltage of the high-side transistor;
a level shift circuit for driving the high-side transistor via the gate protection circuit; and
a pre-driver circuit for driving the level shift circuit and the low-side transistor,
wherein a connection point of the high-side transistor and the low-side transistor serves as an output terminal, and
the level shift circuit interrupts a current path from the output terminal to the level shift circuit after a predetermined time has passed since the high-side transistor was switched OFF.

8. The output circuit of claim 7, wherein
the level shift circuit goes to a high-impedance state after the high-side transistor is switched OFF, thereby interrupting the current path.

9. The output circuit of claim 7, further comprising:
a delay line including a plurality of inverters connected to each other in series, for setting the predetermined time.

10. The output circuit of claim 7, wherein
the predetermined time is longer than a time required for the high-side transistor to be completely switched OFF.

11. The output circuit of claim 9, wherein
the delay line cancels the interruption of the current path without setting the predetermined time.

12. A multi-output circuit comprising:
a plurality of output circuits, wherein each output circuit is the output circuit of claim 7;
a shift register for successively outputting outputs of the output circuits; and
one or more delay lines each including a plurality of inverters connected to each other in series, for setting the predetermined times for the respective corresponding level shift circuits.

13. An output circuit comprising:
a high-side transistor;
a low-side transistor;
a gate protection circuit for protecting a gate voltage of the high-side transistor;
a level shift circuit for driving the high-side transistor via the gate protection circuit; and
a pre-driver circuit for driving the level shift circuit and the low-side transistor,
wherein a connection point of the high-side transistor and the low-side transistor serves as an output terminal, and
the output circuit further comprises a diode between the level shift circuit and the gate protection circuit.

14. An output circuit comprising:
a high-side transistor;
a high-side recirculating diode connected in parallel with the high-side transistor;
a low-side transistor;
a low-side recirculating diode connected in parallel with the low-side transistor;
a gate protection circuit for protecting a gate voltage of the high-side transistor;
a level shift circuit for driving the high-side transistor via the gate protection circuit; and
a pre-driver circuit for driving the level shift circuit and the low-side transistor,
wherein a connection point of the high-side transistor and the low-side transistor serves as an output terminal, and
the output circuit further comprises a diode between the level shift circuit and the gate protection circuit.
